(19) United States
(12) Patent Application Publication
(10) Pub. No.: US 2019/0020340 A1
(43) Pub. Date: Jan. 17, 2019

(54) HYBRID CAPACITIVE KEYPAD

(71) Applicant: Enterprise Electronics LLC, Rochester Hills, MI (US)

(72) Inventor: David J. Pearson, Romeo, MI (US)

(21) Appl. No.: 16/035,780

(22) Filed: Jul. 16, 2018

Related U.S. Application Data
(60) Provisional application No. 62/533,063, filed on Jul. 16, 2017.

(51) Int. Cl. H03K 17/96; G06F 3/044; G06F 3/0354; B60K 35/00

(52) U.S. Cl. CPC H03K 17/9622; G06F 3/044; G06F 3/03547; B60K 2350/1036; H03K 2217/96074; H03K 2217/0036; B60K 35/00

(57) ABSTRACT

A keypad system uses capacitive touch switches in combination with one or more mechanical switches for ultra-low-power operation and/or increased functionality. A Capacitive switches are activated by touching different regions of a housing. A microcontroller detects the activation of the touch switches and communicate a code to a remote device in response to switch activation. The microcontroller preferably has a fully operational active state and a reduced functionality sleep state. Activation of at least one mechanical switch causes the microcontroller to awaken from the reduced functionality sleep state to the fully operational active state, thereby enabling the microcontroller to determine if one or more of the capacitive switches has been activated to communicate a corresponding code to the remote device. While ideally suited to vehicle-mounted keyless entry systems, the apparatus and methods find wider applicability in diverse fields of use.

### REFERENCE TO RELATED APPLICATIONS

This invention application claims priority to, and the benefit of, U.S. Provisional Patent Application Ser. No. 62/533,063, filed Jul. 16, 2017, the entire content of which is incorporated herein by reference.

### FIELD OF THE INVENTION

This invention relates generally to manually operated keypads and, more particularly, to a keypad system that uses capacitive touch switches in combination with one or more mechanical switches for ultra-low-power operation and/or increased functionality.

### BACKGROUND OF THE INVENTION

One of the primary drawbacks to using capacitive sensing switches in battery powered applications is that they require constant switch monitoring and current draw when waiting for activation. A typical capacitive sensing solution requires the microcontroller to “poll” the capacitive sensor by using a timer to “wake up” the processor, enable the capacitive sensor and check for a key press. However, power is consumed at all times by an interval timer that determines the time between key-press checks, and the power consumed when the timer commands a wake-up to use the capacitive sensor to check for a key press

Additionally, when using a small lithium coin cells at low temperatures with high current draw, the internal resistance of the battery increases significantly. A method to counteract this internal resistance increase is the inclusion of a high value of capacitance across the battery, acting as an energy storage reservoir. When using large values of capacitance for energy storage, the leakage currents in the capacitors at high temperatures will reduce the battery life significantly.

### SUMMARY OF THE INVENTION

This invention resides in a keypad system that uses capacitive touch switches in combination with one or more mechanical switches for ultra-low-power operation and/or increased functionality. The invention is particularly applicable to vehicle-mounted keyless entry systems, though the apparatus and methods disclosed herein find wider applicability in other fields of use.

In terms of apparatus, a keypad system according to the invention includes a housing and a plurality of capacitive switches activated by touching different regions of the outer surface of the housing. A battery is disposed in the housing along with electronics operative to detect the activation of the touch switches and communicate a code to a remote device in response to the switch activation. The electronics disposed in the housing includes a microcontroller having a fully operational active state and a reduced functionality sleep state.

The system further includes a mechanical switch that is activated by applying mechanical pressure to the outer surface of the housing. Activation of the mechanical switch causes the microcontroller disposed in the housing to awaken from the reduced functionality sleep state to the fully operational active state, thereby enabling the microcontroller to determine if one or more of the capacitive switches on the outer surface of the housing has been activated and communicate a corresponding code to the remote device.

The housing may be adapted for mounting on a vehicle, and the code may correspond to entering or operating the vehicle. For example, the code corresponds to a DOOR LOCK or UNLOCK function.

The housing may be configured to move toward and away from the mounting plate, in which case the mechanical switch may be activated when the housing is moved toward the mounting plate.

The outer surface of the housing may have a right side and a left side, and the system may include a pair of mechanical switches, one that is activated when the right side of the housing is depressed toward the mounting plate, and another switch that is activated when the left side of the housing is depressed toward the mounting plate. The housing may be spaced apart from the mounting plate by a distance sufficient to impart a tactile feedback to a user when the mechanical switch is activated.

The microcontroller may scan the capacitive switches after the mechanical switch is activated, or at the same time that the mechanical switch is activated. The mechanical switch may be connected directly to the battery, such that no power is consumed by the electronics disposed in the housing until the mechanical switch is activated. Activation of the mechanical switch may trigger a latch circuit, for example, causing the microcontroller to remain in the fully operational active state for a predetermined period of time or until the code is communicated, at which time the microcontroller automatically returns to the reduced functionality sleep state.

The keypad system may include five capacitive keys arranged in a 1×5 key array, with a single key representing a 1 or 2, 3 or 4, 5 or 6, 7 or 8, or a 9 or 0, and right and left mechanical switches, and wherein the activation of the mechanical switches may be used to modify the detection of the capacitive key closures, for example, expanding the 1×5 key array into a 2×5 key array.

### BRIEF DESCRIPTION OF THE DRAWINGS

FIG. 1 is a schematic diagram used to illustrates an exemplary embodiment of the invention; and

FIG. 2 is an exploded view of a keypad constructed in accordance with this invention.

### DETAILED DESCRIPTION OF THE PREFERRED EMBODIMENTS

This invention, referred to herein as a hybrid capacitive keypad, eliminates current draw when waiting for activation, and may include tactile feedback when activating a switch. Also, by placing the storage capacitors on the “switched side” of the transistor, the hybrid capacitive keypad eliminates the constant capacitor leakage current from draining the battery. The tradeoff is the time required to charge the capacitor when the capacitor and microcontroller are connected to the battery.

While the invention finds utility in any environment that could benefit from reduced power consumption, one non-limiting embodiment includes on-vehicle mounting for keyless entry, for example. This implementation may have five keys with a single key representing a 1 or 2, 3 or 4, 5 or 6, 7 or 8, 9 or 0. These five keys use a PCB trace connected to a capacitive sensing circuit and software on one of many capacitive sensing capable microcontrollers.

The hybrid feature may utilizes at least one extra mechanical switch to allow the power to the microcontroller to be completely turned off by an external transistor switch. Alternatively, the microcontroller can enter its lowest power sleep state and wait for the mechanical switch to generate an interrupt to wake microcontroller from its sleep state. These mechanical switch arrangements can work in multiple ways, as described below:

In one embodiment, a mechanical switch is used as a sixth key or a “wake-up key.” When pressed, it wakes the microcontroller, which then enters its active state and senses capacitive key activations. This switch can also serve as a function switch allowing two button key-presses. For example, in a vehicle keyless entry implementation, pressing the sixth (function key) together with the 9/0 key would send a Lock command, to increase available key functions.

Alternatively, if the mechanical switch(s) are configured such that when a keypad capacitive button is pressed, this mechanical pressure is transferred as a force pressing on a mounting base, the contact point from the keypad to mounting base being a mechanical switch. As such, when the button area on any of the five capacitive keys is pressed, a mechanical switch closure occurs, waking the microcontroller.

If mechanical switches are placed on the left and right side or long edge of the keypad, and the keypad center is used as a pivot point, left and right activation can be sensed. Using this left/right rocking switch sensing combined with the capacitive switch sensing, a ten (10-key) keypad is feasible in the same footprint as a five-key keypad. If the left side of the keypad is pressed, the keypad will rock to the left closing the left switch. When the keypad wakes, it senses which switch is pressed, left or right, and then senses using capacitance change which key is pressed. As such, a left press on the 1/2 key would result in a 1 key and a right press on the 1/2 key would result in a 2 key. This would increase the number of unique code entries with a five digit code from 3125 to 100,000.

For all of the above embodiments, the same wake-up process applies. Upon wake-up, the microcontroller sends a signal which holds the transistor power switch ON, which keeps the microcontroller powered, which then uses its capacitive sensing to determine which switch has been activated. When the microcontroller returns to sleep mode, the transistor switch is turned off, depowering the microcontroller and minimizing OFF current.

The arrangements made possible by the invention offer numerous features and benefits, including capacitive switch sensing with near-zero sleep current. Sleep current drain is essentially battery self-discharge, allowing the use of smaller and thinner batteries. High value capacitors with high leakage current can also be used for energy storage.

The capacitive switches also allow for a flat-faced, sealed keypad. No apertures are required for keys, resulting in a simpler keypad face. False activations are also minimized due to the mechanical wake-up. In a vehicle entry system, car wash activations can be eliminated by requiring constant mechanical pressure on keypad while capacitive sensing key presses.

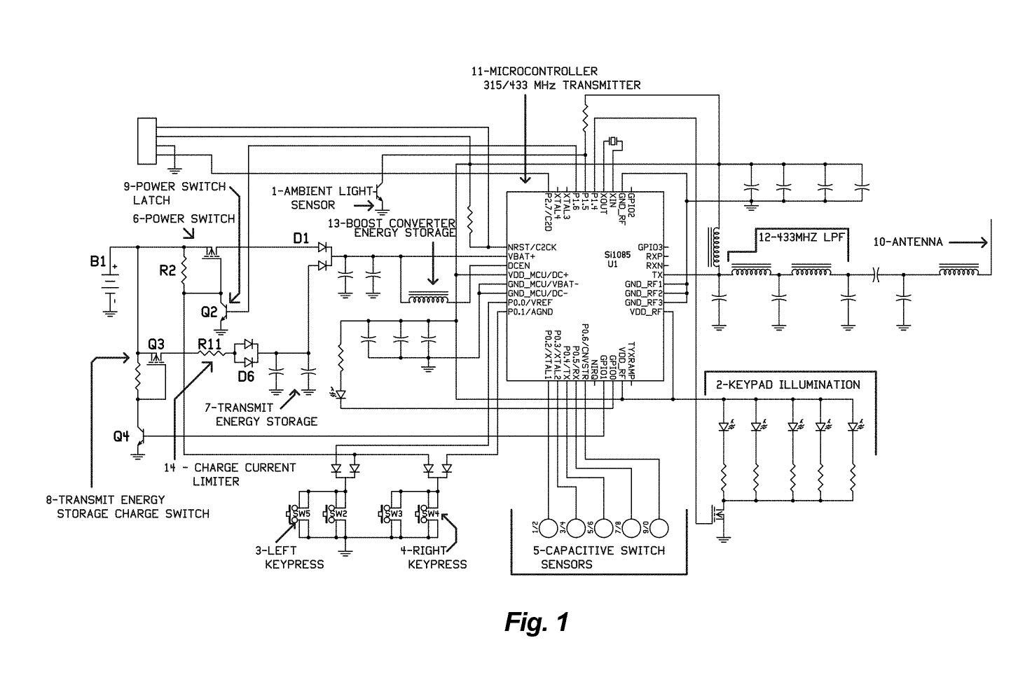

The invention also facilitates a simpler key illumination implementation. A capacitive keypad may provide tactile feedback via the mechanical wake-up switch(es). With a center pivot point, a side-to-side rocking switch can implement a 10 key keypad in a 5 key footprint. FIG. 1 is a schematic diagram used to illustrates an exemplary embodiment of the invention including provisions for vehicle keyless entry. While component values and other information has been left off for the sake of clarity, such details are available in the Provisional Application Ser. No. 62/533,063, the entire content of which is incorporated herein by reference.

Before the system awakes, the microcontroller (11) is powered OFF and disconnected from the power source by the P-channel MOSFET POWER SWITCH (6). The battery is also disconnected from the TRANSMIT ENERGY STORAGE (7) by the P-channel MOSFET TRANSMIT ENERGY STORAGE CHARGE SWITCH (8). This enables the device to have its sleep current draw defined by the leakage current of transistors Q4 and Q2 through R2.

When the face of the keypad is either pressed in or, in the case of a 10-key keypad, pressed on the right or left side, the complete keypad will move inward toward the fixed mount. This movement (about 0.3 mm) will press a switch mounted, LEFT KEYPRESS (3) or RIGHT KEYPRESS (4) in the back of the keypad top downward against an actuator on the fixed mount. This switch functions as a wake-up switch. If the keypad is configured for 10-key operation, the LEFT KEYPRESS will activate when the keypad is pressed on the left side and the RIGHT KEYPRESS will activate on a right key-press. If set for 5-key operation, the keys will active on any press on the keypad surface. These keys also provide tactile feedback on switch activation, usually missing with capacitive switches.

After the wake-up switch is pressed, a current path is provided from the gate the POWER SWITCH (6) to ground which turns the POWER SWITCH ON. Battery power is now provided to the MICROCONTROLLER (11). The MICROCONTROLLER (11) wakes and places a high voltage on the base of transistor Q2, POWER SWITCH LATCH (9). This transistor has an internal base input and pull-down resistor, holding it in the off state, which provides a current path from the gate of the POWER SWITCH (6) holding the power to the microcontroller ON. The internal boost converter will turn on, holding the microcontroller voltage at 3.3 volts.

With the MICROCONTROLLER (11) now powered and executing instructions, the MICROCONTROLLER will sense, via capacitive change, which key of the CAPACITIVE SWITCH SENSORS (5) has been pressed. Once a key has been sensed, a high level will be placed on the base of transistor Q4, turning on the TRANSMIT ENERGY STORAGE CHARGE SWITCH (8), allowing the TRANSMIT ENERGY STORAGE (7) capacitors to charge. These capacitors store enough energy to transmit up-to 9 packets of data. These capacitors store energy that can power the keypad under extreme cold and a weak battery that exhibits high internal resistance, thereby allowing operation throughout the operating temperature range, including vehicular applications. A diode OR function allows either the TRANSMIT ENERGY STORAGE (7) or the battery to power the keypad. The dual diode Dl prevents the battery from charging the TRANSMIT ENERGY STORAGE (7) capacitor continuously.

During the MICROCONTROLLER (11) startup, after a mechanical key-press, the AMBIENT LIGHT SENSOR (1) will provide a voltage inversely proportional to the ambient light level. If the voltage from the sensor is below a certain threshold, the KEYPAD ILLUMINATION (2) will NOT turn on. If the ambient light level is above the threshold the illumination will turn on until timeout occurs after keypad operation.

Upon successful user code entry or a LOCK key sequence, for example, the MICROCONTROLLER (11) will calculate the proper packet and transmit it via the internal PLL synthesized transmitter connected to the 433 MHz LPF (12), which reduces spurious harmonics emanating from the ANTENNA (10). During transmit, the power for the transmitter will come from both the TRANSMIT ENERGY STORAGE (7) and the battery B1. When the system shuts down, the MICROCONTROLLER (11) will turn off the TRANSMIT ENERGY STORATE CHARGE SWITCH (8) and turn off the POWER SWITCH LATCH (9) removing all power from the MICROCONTROLLER (11).

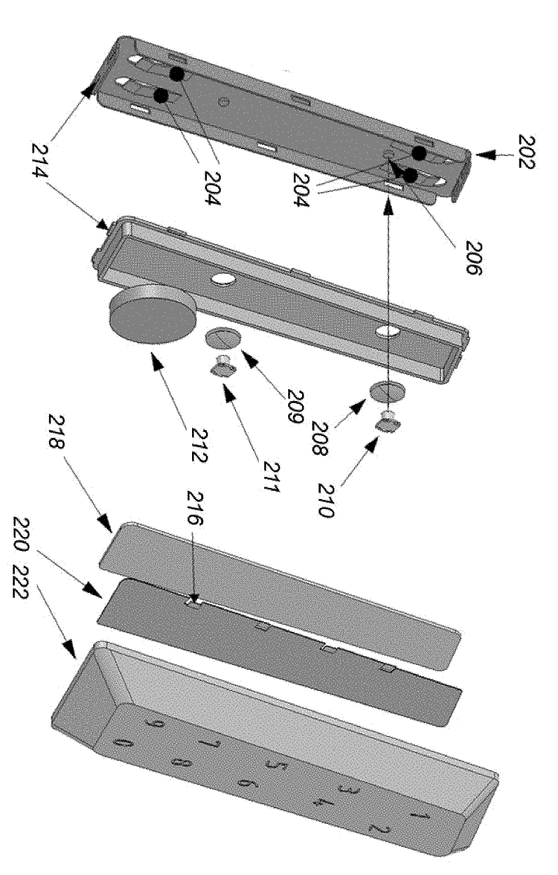

FIG. 2 is an exploded view of a vehicle-mounted keypad constructed in accordance with this invention. A mounting plate 202 is used to affix the sealed keypad assembly shown to a surface of a vehicle. The keypad base is allowed to move relative to the mounting plate 202 by way of a slot and tab assembly 214. Right and left mechanical switches 210, 211, are aligned with actuator presses 206 through over-molded thermoplastic polyurethane (TPU) inserts 208, 209, respectively, such that when one of the sides on the keypad assembly is pressed, the actuator presses activate one or the other of the switches 210, 211. Spring members 204 hold the keypad assembly spaced apart from the mounting base until one side of the assembly is pressed.

The outer keypad assembly includes an outer shell 222 with numerical indicators, a light guide film 220, and printed-circuit board assembly 218. LEDs 216 are activated when the outer shell is pressed, causing at least the numerical indicators to illuminate through the light guide film 220. The battery is indicated at 212.

The assembly depicted in FIG. 2 may be used to illustrate various embodiments of the invention. For example, If a user presses one of the numbered regions on the outer shell, this action may be used simply to wake up the microcontroller through one of the mechanical switches, whether or not the number pressed is used to generate a code for LOCK, UNLOCK, or other vehicle functionality. While two stitches are shown, a single switch (i.e. centrally located), may be used if the goal is to wake up the microcontroller without increasing the number of useable codes.

1. A keypad system, comprising:
a housing having an outer surface;
a plurality of capacitive switches activated by touching different regions of the outer surface of the housing;
a battery and electronics disposed in the housing, the electronics being operative to detect the activation of the touch switches and communicate a code to a remote device in response to the switch activation;
wherein the electronics disposed in the housing includes a microcontroller having a fully operational active state and a reduced functionality sleep state;
a mechanical switch that is activated by applying mechanical pressure to the outer surface of the housing; and
wherein activation of the mechanical switch causes the microcontroller disposed in the housing to awaken from the reduced functionality sleep state to the fully operational active state, thereby enabling the microcontroller to determine if one or more of the capacitive switches on the outer surface of the housing has been activated and communicate a corresponding code to the remote device.

2. The keypad system of claim 1, wherein:
the housing is adapted for mounting on a vehicle; and
the code corresponds to entering or operating the vehicle.

3. The keypad system of claim 2, wherein the code corresponds to a DOOR LOCK or UNLOCK function.

4. The keypad system of claim 1, further including a mounting plate;
wherein the housing is configured to move toward and away from the mounting plate; and
the mechanical switch is activated when the housing is moved toward the mounting plate.

5. The keypad system of claim 1, wherein the outer surface of the housing has a right side and a left side; and
further including a pair of mechanical switches, one that is activated when the right side of the housing is depressed toward the mounting plate, and another switch that is activated when the left side of the housing is depressed toward the mounting plate.

6. The keypad system of claim 1, wherein the housing is spaced apart from the mounting plate by a distance sufficient to impart a tactile feedback to a user when the mechanical switch is activated.

7. The keypad system of claim 1, wherein the microcontroller scans the capacitive switches after the mechanical switch is activated.

8. The keypad system of claim 1, wherein the microcontroller scans the capacitive switches at the same time that the mechanical switch is activated.

9. The keypad system of claim 1, wherein the mechanical switch is connected directly to the battery, such that no power is consumed by the electronics disposed in the housing until the mechanical switch is activated.

10. The keypad system of claim 1, wherein activation of the mechanical switch triggers a latch circuit, causing the microcontroller to remain in the fully operational active state for a predetermined period of time or until the code is communicated, at which time the microcontroller automatically returns to the reduced functionality sleep state.
is connected directly to the battery, such that no power is consumed by the electronics disposed in the housing until the mechanical switch is activated.

11. The keypad system of claim 1, including five capacitive keys arranged in a 1×5 key array, with a single key representing a 1 or 2, 3 or 4, 5 or 6, 7 or 8, or a 9 or 0.

12. The keypad system of claim 11, including right and left mechanical switches; and
wherein the activation of the mechanical switches is used to modify the detection of the capacitive key closures, thereby expanding 1×5 key array to a 2×5 key array.

13. The keypad system of claim 1, wherein the code communicated to the remote device is contained in a wireless signal.
